(19) United States
(12) Patent Application Publication
(10) Pub. No.: US 2025/0183510 A1
(43) Pub. Date: Jun. 5, 2025

(54) GYSEL COMBINER AND GYSEL COMBINED APPARATUS FREE FROM SIGNAL INTERFERENCE

(71) Applicant: WAVEPIA CO., LTD., Gyeonggi-do (KR)

(72) Inventors: Sang-Hun LEE, Gyeonggi-do (KR); Tae-Hoon LEE, Gyeonggi-do (KR); Chang-Seo PARK, Gyeonggi-do (KR); Ki-Wook LEE, Gyeonggi-do (KR)

(21) Appl. No.: 18/954,823

(22) Filed: Nov. 21, 2024

(30) Foreign Application Priority Data
Dec. 5, 2023 (KR) 10-2023-0174575

(51) Int. Cl. H01P 5/16; H01P 3/00; H05K 1/02

(52) U.S. Cl. CPC H01P 5/16; H01P 3/00; H05K 1/0237

(57) ABSTRACT

A Gysel combiner free from signal interference includes a first transmission line connected to a first port, a 12 transmission line connected between the first transmission line and a second port, a 13 transmission line connected between the first transmission line and a third port, a 24 transmission line connected between the 12 transmission line and a fourth port, a 35 transmission line connected between the 13 transmission line and a fifth port, a 45-1 transmission line connected to the 24 transmission line, and a 45-2 transmission line connected between the 45-1 transmission line and the fifth port, on a printed circuit board.

### BACKGROUND

The present invention relates to a Gysel combiner and a Gysel combined apparatus free from signal interference, and more particularly, to a Gysel combiner and a Gysel combined apparatus free from signal interference, which can effectively suppress signal interference that may occur between an output port and an isolation port by forming a ground plane between the output port and the isolation port and disposing a vertical stub on an upper surface of the ground plane.

In general, in wireless communication systems, power combiners or divider circuits are used as a RF (Radio Frequency) signal power amplifiers that amplify and output the power of RF signals.

The power divider/combiner circuit described above is a very important element in the application of RF signal circuits or systems, and according to the implementation method thereof, there is a method of implementing it using a core, a method of implementing it by printing microstrip lines on a substrate, a method of implementing it using a 3 dB hybrid combiner, or the like.

Meanwhile, power divider/combiner circuits have been developed as a type that combines the outputs of multiple solid-state power amplifiers or oscillators, and have been developed in various shapes.

Recently, the Gysel-type power divider has been in the spotlight because the number of input ports and output ports is asymmetrical. The Gysel power divider uses two termination resistors to improve the isolation performance between the output terminals.

However, as the size of the Gysel-type power divider decreases, the gap between the output port and the isolation port narrows, causing signal interference between the ports.

In particular, as the output of the Gysel-type power divider increases, the frequency of signal interference between the ports described above increases, causing a problem of deterioration in isolation performance.
Patent Document 1: Republic of Korea Registered Patent No. 10-1929366 (Dec. 10, 2018).

### SUMMARY OF THE INVENTION

An object of the present invention is to provide a Gysel combiner free from signal interference, which can effectively suppress signal interference that may occur between an output port and an isolation port by forming a ground plane between the output port and the isolation port and disposing a vertical stub on the upper surface of the ground plane.

In addition, another object of the present invention is to provide a Gysel combined apparatus free from signal interference, including the above-described Gysel combiner.

The technical problems to be solved by the present invention are not limited to the technical problems mentioned above, and unmentioned other technical problems can be clearly understood by those of skilled in the art from the following description.

To achieve the above object, a Gysel combiner free from signal interference according to an embodiment of the present invention consists of a first transmission line connected to a first port, a 12 transmission line connected between the first transmission line and a second port, a 13 transmission line connected between the first transmission line and a third port, a 24 transmission line connected between the 12 transmission line and a fourth port, a 35 transmission line connected between the 13 transmission line and a fifth port, a 45-1 transmission line connected to the 24 transmission line, and a 45-2 transmission line connected between the 45-1 transmission line and the fifth port, on a printed circuit board, in which a ground plane is formed within an area formed by the 12 transmission line, the 24 transmission line, the 45-1 transmission line, the 45-2 transmission line, the 35 transmission line, and the 13 transmission line, and a vertical stub is disposed on the ground plane in a vertical direction in a state of being connected to the ground plane.

Preferably, the vertical stub may be formed of Al, Au, or Ag.

Preferably, the vertical stub may be formed in a rectangular parallelepiped shape.

Preferably, a plurality of vertical stubs may be disposed.

Preferably, the vertical stub may be formed in a cylindrical shape.

To achieve the above object, a Gysel combined apparatus free from signal interference according to an embodiment of the present invention includes a Gysel combiner consisting of a first transmission line connected to a first port, a 12 transmission line connected between the first transmission line and a second port, a 13 transmission line connected between the first transmission line and a third port, a 24 transmission line connected between the 12 transmission line and a fourth port, a 35 transmission line connected between the 13 transmission line and a fifth port, a 45-1 transmission line connected to the 24 transmission line, and a 45-2 transmission line connected between the 45-1 transmission line and the fifth port, on a printed circuit board, in which a ground plane is formed within an area formed by the 12 transmission line, the 24 transmission line, the 45-1 transmission line, the 45-2 transmission line, the 35 transmission line, and the 13 transmission line, and in which a lower cover is disposed on the lower part of the Gysel combiner, a side cover is disposed on the side of the Gysel combiner, an upper cover is disposed on the upper part of the Gysel combiner in a state of being spaced apart from the Gysel combiner, a screw is disposed vertically through the upper cover and connected to the ground plane, and a nut is assembled to the screw so as to fasten the Gysel combiner and the upper cover.

Preferably, the screw may be formed of Al, Au, or Ag.

A Gysel combiner free from signal interference according to embodiments of the present invention can effectively suppress signal interference that may occur between an output port and an isolation port by forming a ground plane between the output port and the isolation port and disposing a vertical stub on an upper surface of the ground plane.

In addition, the Gysel combined apparatus free from signal interference according to embodiments of the present invention can effectively suppress signal interference that may occur between the output port and the isolation port by forming a ground plane between the output port and the isolation port and disposing a screw vertically on the upper surface of the ground plane.

### BRIEF DESCRIPTION OF THE DRAWINGS

FIG. 1 is a circuit diagram showing a Gysel combiner free from signal interference according to embodiments of the present invention.

FIG. 2 is a view showing a circuit board implementing a Gysel combiner free from signal interference according to one embodiment of the present invention.

FIG. 3 is a view showing a circuit board implementing a Gysel combiner free from signal interference according to another embodiment of the present invention.

FIG. 4 is a view showing a circuit board implementing a Gysel combiner free from signal interference according to another embodiment of the present invention.

FIG. 5 is a view showing a cross-section of a Gysel combined apparatus free from signal interference according to one embodiment of the present invention.

### DETAILED DESCRIPTION OF THE PREFERRED EMBODIMENT

The detailed description of the present invention that follows refers to the accompanying drawings that illustrate specific embodiments in which the present invention may be practiced. These embodiments are described in sufficient detail to enable those of skilled in the art to practice the present invention. It should be understood that the various embodiments of the present invention, while different from each other, are not necessarily mutually exclusive.

For example, the specific shapes, structures, and characteristics described herein may be implemented in other embodiments without departing from the spirit and scope of the present invention with respect to one embodiment. It should also be understood that the location or disposition of individual components within each disclosed embodiment may be changed without departing from the spirit and scope of the present invention.

Accordingly, the detailed description set forth below is not intended to be taken in a limiting sense, and the scope of the present invention is defined only by the appended claims, along with the full scope equivalent to assorted by the claims, if properly described.

Hereinafter, a Gysel combiner free from signal interference according to embodiments of the present invention will be described with reference to the attached drawings.

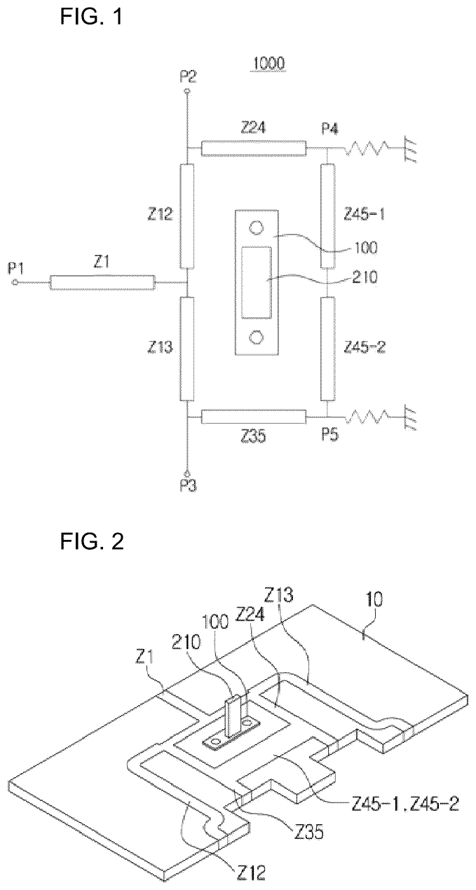

A Gysel combiner free from signal interference according to one embodiment of the present invention consists of, as shown in FIG. 1, a first transmission line Z1 connected to a first port P1, a 12 transmission line Z12 connected between the first transmission line Z1 and a second port P2, a 13 transmission line Z13 connected between the first transmission line Z1 and a third port P3, a 24 transmission line Z24 connected between the 12 transmission line Z12 and a fourth port P4, a 35 transmission line Z35 connected between the 13 transmission line Z13 and a fifth port P5, a 45-1 transmission line Z45-1 connected to the 24 transmission line Z24, and a 45-2 transmission line Z45-2 connected between the 45-1 transmission line Z45-1 and the fifth port P5 on a printed circuit board 10. Here, each transmission line is formed with a length of λ/4, the first port P1 is an input port, the second port P2 and the third port P3 are output ports, and the fourth port P4 and the fifth port P5 are isolation ports.

Meanwhile, in a Gysel combiner free from signal interference according to an embodiment of the present invention, as illustrated in FIG. 2, a ground plane 100 is formed within an area formed by the 12 transmission line Z12, the 24 transmission line Z24, the 45-1 transmission line Z45-1, the 45-2 transmission line Z45-2, the 35 transmission line Z35, and the 13 transmission line Z13, and a vertical stub 210 is disposed in a vertical direction on the ground plane 100 in a state of being connected to the ground plane 100. Here, the vertical stub 210 may be formed of Al, Au, or Ag.

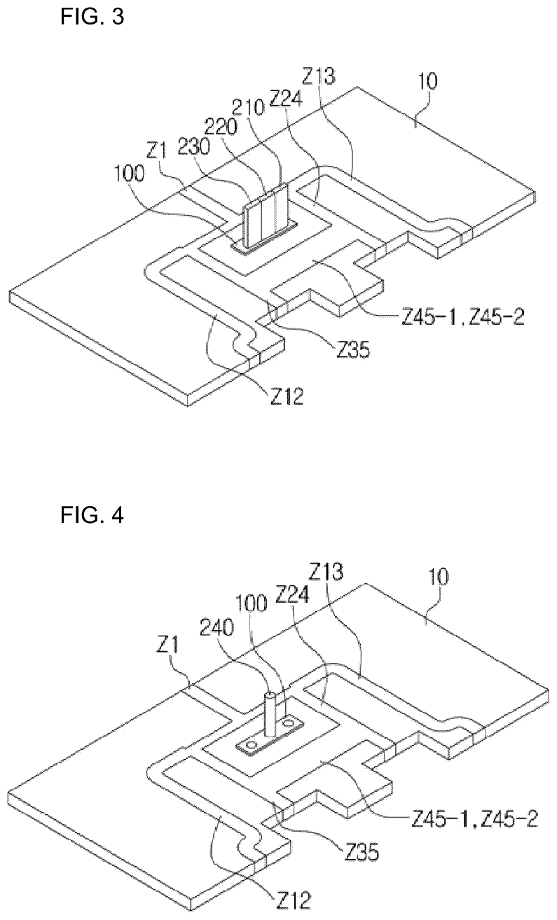

Specifically, the vertical stub 210 may be formed in a rectangular hexahedron shape as shown in FIG. 2, and a plurality of vertical stubs 210, 220, 230 may be disposed as shown in FIG. 3, if necessary.

Meanwhile, the vertical stub 240 may be formed in a cylindrical shape as shown in FIG. 4, and a plurality of vertical stubs may be disposed, if necessary.

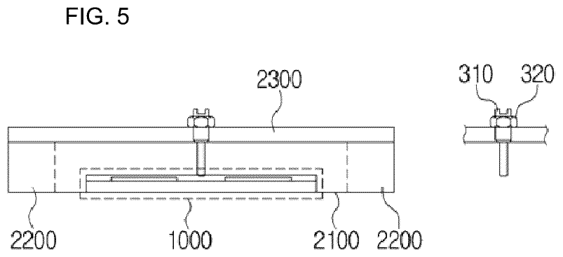

Hereinafter, a Gysel combined apparatus free from signal interference according to one embodiment of the present invention will be described with reference to FIG. 5.

A Gysel combined apparatus free from signal interference according to one embodiment of the present invention includes a Gysel combiner 1000 consisting of a first transmission line Z1 connected to a first port P1, a 12 transmission line Z12 connected between the first transmission line Z1 and a second port P2, a 13 transmission line Z13 connected between the first transmission line Z1 and a third port P3, a 24 transmission line Z24 connected between the 12 transmission line Z12 and a fourth port P4, a 35 transmission line Z35 connected between the 13 transmission line Z13 and a fifth port P5, a 45-1 transmission line Z45-1 connected to the 24 transmission line Z24, and a 45-2 transmission line Z45-2 connected between the 45-1 transmission line Z45-1 and the fifth port P5 on a printed circuit board 10.

Here, the above-described Gysel combiner 1000 also has a ground plane 100 formed within an area formed by the 12 transmission line Z12, the 24 transmission line Z24, the 45-1 transmission line Z45-1, the 45-2 transmission line Z45-2, the 35 transmission line Z35, and the 13 transmission line Z13.

Meanwhile, according to an embodiment of the present invention, in a Gysel combined apparatus free from signal interference, as illustrated in FIG. 5, a lower cover 2100 is disposed on the lower part of the Gysel combiner 1000, a side cover 2200 is disposed on the side of the Gysel combiner, an upper cover 2300 is disposed on the upper part of the Gysel combiner in a state of being spaced apart from the Gysel combiner, a screw 310 is disposed vertically through the upper cover 2300 and connected to the ground plane 100, and a nut 320 is assembled to the screw 310 so as to fasten the Gysel combiner 1000 and the upper cover 2300. Here, the screw 310 may be formed of Al, Au, or Ag.

While the present invention has been described and illustrated with reference to preferred embodiments for illustrating the principles of the present invention, the present invention is not limited to the exact construction and operation illustrated and described.

Rather, those of skilled in the art will readily appreciate that many modifications and variations of the present invention are possible without departing from the spirit and scope of the appended claims.

Accordingly, all such appropriate modifications and variations and equivalents should be considered to fall within the scope of the present invention.

What is claimed is:

1. A Gysel combiner free from signal interference, the Gysel combiner consisting of a first transmission line connected to a first port, a 12 transmission line connected between the first transmission line and a second port, a 13 transmission line connected between the first transmission line and a third port, a 24 transmission line connected between the 12 transmission line and a fourth port, a 35 transmission line connected between the 13 transmission line and a fifth port, a 45-1 transmission line connected to the 24 transmission line, and a 45-2 transmission line connected between the 45-1 transmission line and the fifth port, on a printed circuit board,
wherein a ground plane is formed within an area formed by the 12 transmission line, the 24 transmission line, the 45-1 transmission line, the 45-2 transmission line, the 35 transmission line, and the 13 transmission line, and
wherein a vertical stub is disposed on the ground plane in a vertical direction in a state of being connected to the ground plane.

2. The Gysel combiner free from signal interference of claim 1, wherein the vertical stub is formed of Al, Au, or Ag.

3. The Gysel combiner free from signal interference of claim 2, wherein the vertical stub is formed in a rectangular parallelepiped shape.

4. The Gysel combiner free from signal interference of claim 3, wherein a plurality of vertical stubs are disposed.

5. The Gysel combiner free from signal interference of claim 2, wherein the vertical stub is formed in a cylindrical shape.

6. The Gysel combiner free from signal interference of claim 1, wherein a plurality of vertical stubs are disposed.

7. A Gysel combined apparatus free from signal interference, the Gysel combined apparatus including a Gysel combiner consisting of a first transmission line connected to a first port, a 12 transmission line connected between the first transmission line and a second port, a 13 transmission line connected between the first transmission line and a third port, a 24 transmission line connected between the 12 transmission line and a fourth port, a 35 transmission line connected between the 13 transmission line and a fifth port, a 45-1 transmission line connected to the 24 transmission line, and a 45-2 transmission line connected between the 45-1 transmission line and the fifth port, on a printed circuit board,
wherein a ground plane is formed within an area formed by the 12 transmission line, the 24 transmission line, the 45-1 transmission line, the 45-2 transmission line, the 35 transmission line, and the 13 transmission line, and
wherein a lower cover is disposed on the lower part of the Gysel combiner, a side cover is disposed on the side of the Gysel combiner, an upper cover is disposed on the upper part of the Gysel combiner in a state of being spaced apart from the Gysel combiner, a screw is disposed vertically through the upper cover and connected to the ground plane, and a nut is assembled to the screw so as to fasten the Gysel combiner and the upper cover.

8. The Gysel combined apparatus free from signal interference of claim 7, wherein the screw is formed of Al, Au, or Ag.
